(19) United States
(12) Patent Application Publication
(10) Pub. No.: US 2004/0178000 A1
(43) Pub. Date: Sep. 16, 2004

(54) Standardized circuit board core

(76) Inventor: Tzyy-Jang Tseng, Hsinchu (TW)

Correspondence Address: J.C. Patents, Inc., Suite 250, 4 Venture, Irvine, CA, 92618, US

(21) Appl. No.: 10/655,845

(22) Filed: Sep. 4, 2003

(30) Foreign Application Priority Data
Mar. 12, 2003 (TW) 92203766

(51) Int. Cl. H05K 1/11

(52) U.S. Cl. 174/264; 174/267

(57) ABSTRACT

A standardized or partial standardized circuit board core comprises at least a dielectric core layer and a plurality of conductive posts, in which the dielectric layer has a first surface and a related second surface. The conductive posts pass through the dielectric core layer and connect to the first and second surfaces of the dielectric layer respectively. The conductive posts are array arranged or arranged in a constant distance form in the dielectric core layer. Moreover, the standardized or partial standardized circuit board core further includes two conductive layers, which are covered on the first and second surfaces of the dielectric core layer.

### CROSS-REFERENCE TO RELATED APPLICATION

This application claims the priority benefit of Taiwan application serial no. 92203766, filed Mar. 12, 2003.

### BACKGROUND OF THE INVENTION

1. Field of the Invention

The invention relates to a circuit board core. More particularly, relates to a standardized circuit board core in which a plurality of conductive posts are prefabricated, and are array arranged or arranged in a constant distance form in the dielectric core layer.

2. Related Art of the Invention

As electronic techniques progress with each passing day, many high-tech industries steadily emerge. More user friendly, powerful electronic products are developed, following the design trend of light, thin, short and small. Every electronic product has at least a main board constituted by many electronic components and circuit boards. The function of the circuit board is to carry and electronically couple with every electronic components. Thus the electronic components can couple with each other electronically. The most common circuit board is the printed circuit board (“PCB”).

FIG. 1A to FIG. 1F show cross-sectional views of a partial flowchart of a prior art of a four-layer circuit conductive layer printed circuit board. As FIG. 1A shows, first a two-surfaced board is provided, which comprises a dielectric core layer 110, a conductive layer 120a and a conductive layer 120b. The conductive layers 120a and 120b are two copper film layers, which are disposed on both of the surfaces of the dielectric core layer 110. Then, as FIG. 1B shows, with mechanical drill or laser drill methods, the dielectric core layer 110 and the two conductive layers 120a and 120b are punched through to provide a plurality of holes 112. Thereafter, as FIG. 1C shows, by using a plating method, a conductive material is disposed on the surfaces of both of the conductive layers 120a and 120b to form two conductive layers 114a and 114b. Moreover, the conductive material is also disposed on the inner surface of the holes 112 to form a plurality of conductive layer 114c. It is worthy of note that the conductive layers 120a and 114a can be regarded as the same conductive layer 122a, and the conductive layers 120b and 114b can be regarded as the same conductive layer 122b.

As FIG. 1D shows, dielectric material 116 is inserted into the hole 112 to prevent hole 112 for generating void. Furthermore, as FIG. 1E shows, with photolithography and etching process, the conductive layers 122a and 122b are patterned to form the desired conductive wire and bonding pad. Finally, as FIG. 1F shows, dielectric layers 130a, 130b and conductive layers 140a, 140b (e.g. two copper film layers) are piled on both of the surfaces of the dielectric core layer 110. Then these layers are laminated to form the half-finished four-layer conductive layer printed circuit board.

In a conventional technology, when using lamination method to manufacture a printed circuit board, a plated through hole method is provided to electrically connect the adjacent or non-adjacent patterned conductive layers of the printed circuit board. In other words, the process including punching the printed circuit board, forming the plated through hole, and inserting the conductive material can electrically connect the adjacent and non-adjacent patterned conductive layers of the printed circuit board. Since the manufacturing process of current printed circuit board is corresponding to specific application specification of the printed circuit boards, longer design and manufacturing period are required for each specific application of the printed circuit board.

### SUMMARY OF THE INVENTION

Accordingly, one object of the present invention is to provide a standardized or partial standardized circuit board core in order to shorten the design and manufacturing period of a printed circuit board and lower down the manufacturing cost.

To achieve these and other advantages and in accordance with the purpose of the invention, as embodied and broadly described herein, the invention provides a standardized or partial standardized circuit board core comprising at least a dielectric core layer and a plurality of conductive posts. The dielectric core layer has a first surface and a related second surface. The conductive posts pass through the dielectric core layer and connect the first and second surfaces of the dielectric core layer. The conductive posts are array arranged or arranged in a constant distance form in the dielectric core layer.

According to the preferred embodiment of the invention, the standardized or partial standardized circuit board core further includes two conductive layers formed on the first and second surfaces of the dielectric core layer respectively.

The standardized or partial standardized circuit board core of the invention provides a plurality of pre-manufactured conductive posts plugging in the dielectric core layer. These plugs are array arranged or arranged in a constant distance form in the dielectric core layer. Therefore, when the standardized or partial standardized circuit board core of the invention is provided for manufacturing a printed circuit board, the plated through hole method applied in the prior art is no more needed to pattern the two-surfaced dielectric core layer. Thus, the PCB manufacturing process is simplified, the design and manufacturing period are reduced, and the PCB manufacturing cost is lowered down.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are cross-sectional views illustrating a process flowchart of a conventional four-layered conductive layer printed circuit board.

FIG. 2A to FIG. 2B are cross-sectional views illustrating a standardized circuit board core having a non-patterned and a patterned conductive layer of a preferred embodiment of the invention.

FIG. 3 is a cross-sectional view illustrating a standardized circuit board core having a four-layered conductive layer of a preferred embodiment of the invention.

FIG. 4A and FIG. 4B are perspective views illustrating a non-patterned and a patterned standardized circuit board core respectively of a preferred embodiment of the invention.

FIG. 5A and FIG. 5B are top views illustrating standardized circuit board cores arranged in two constant distance forms respectively of a preferred embodiment of the invention.

FIG. 6 is a top view illustrating a standardized circuit board core having conductive posts partially plugged in a partial standardized circuit board core of a preferred embodiment of the invention.

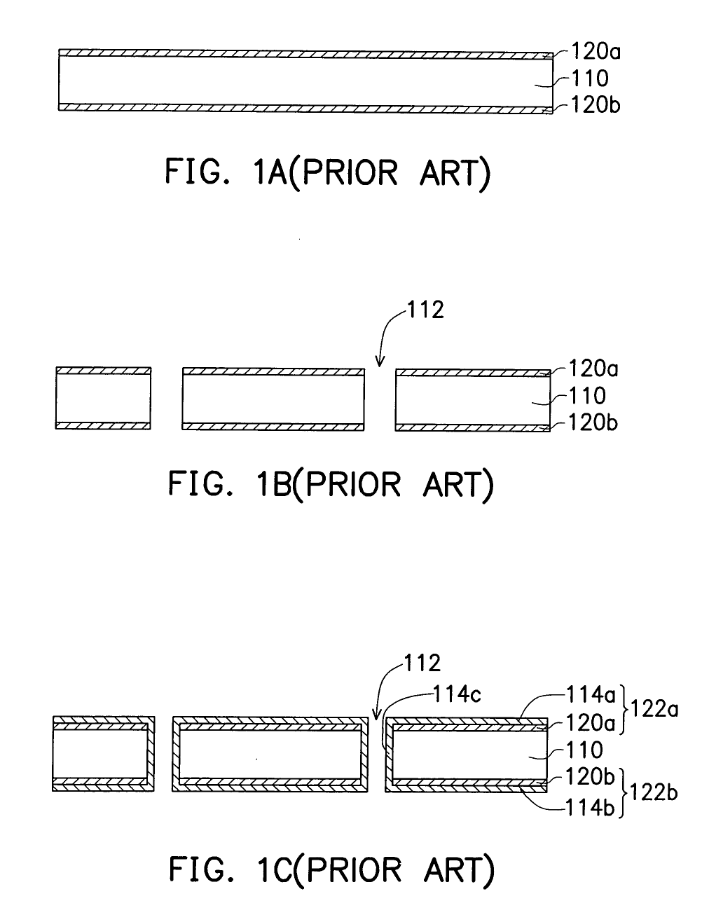

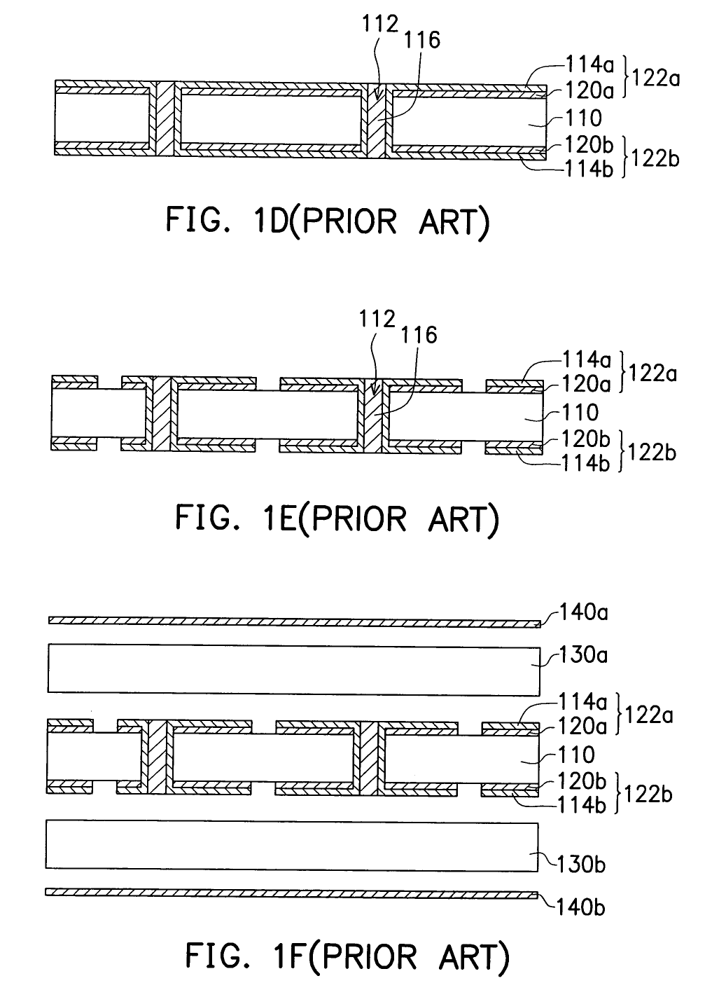

### DETAILED DESCRIPTION OF THE PREFERRED EMBODIMENT

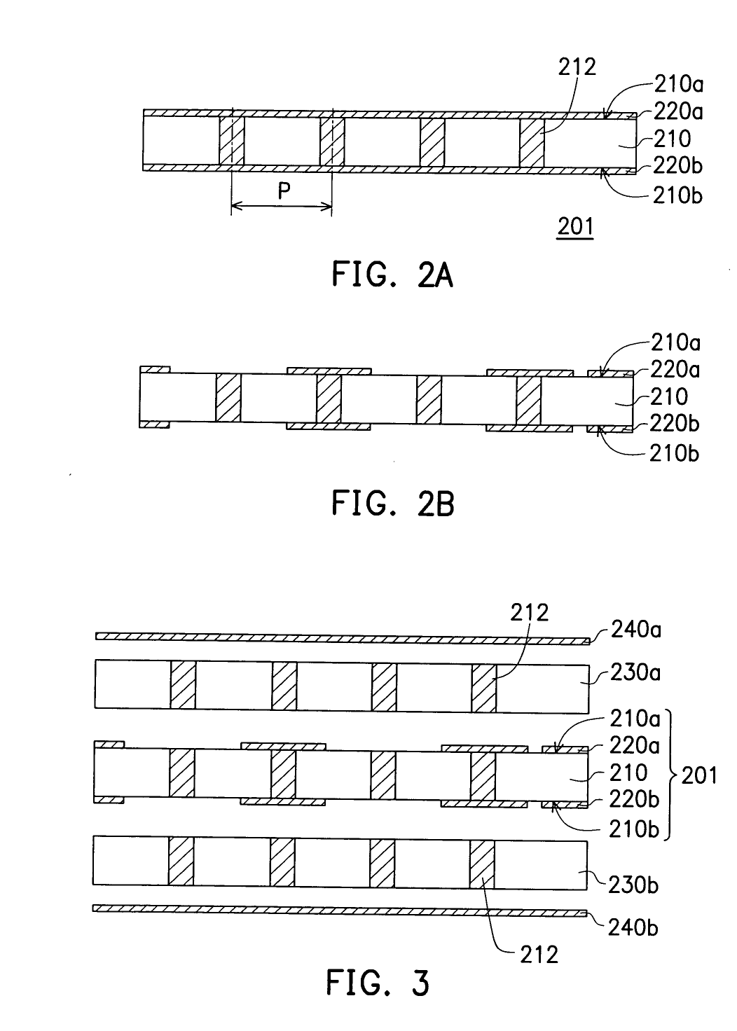

Referring to FIG. 2A and FIG. 2B, cross-sectional views of a standardized circuit board core having a non-patterned and a patterned conductive layer of a preferred embodiment of the invention are illustrated. Although an embodiment of a four-layered conductive layer of a PCB is provided in FIG. 2A and FIG. 2B, but the scope of the invention can also be extended to a PCB having other than four-layered conductive layer. First of all, referring to FIG. 2A, a standardized circuit board core 201 including a dielectric core layer 210 and a plurality of conductive posts 212. The dielectric core layer 210 has a first surface 210a and a related second surface 210b. The conductive posts 212 pass through the dielectric core layer 210 and connect to the first surface 210a and second surface 210b. The conductive posts 212 are array arranged or arranged in a constant distance form in the dielectric core layer, and P is a distance between any two nearest conductive posts 212. The material of the dielectric core layer 210 includes, but not limited to, a resin with glass fiber, which is provided for strengthening the structure of dielectric core layer 210. The material of the dielectric core layer 210 further includes polymer, polyamide or liquid crystal polymer.

Referring to FIG. 2A, the standardized circuit board core 201 further includes conductive layers 220a and 220b formed on the first surface 210a and second surface 210b of the dielectric core layer 210 respectively. The material of the conductive layers 220a and 220b is a material having good conductivity includes, but not limited to, copper, metal or electrical conductive compounds. The conductive layers 220a and 220b can also be compound metal layers. As shown in FIG. 2B, photolithography and etching methods are used to pattern the conductive layers 220a and 220b. Thus the conductive wires and the bonding pads are formed from the patterned layers 220a and 220b, and a semi-product of a double-side PCB is provided.

Referring FIG. 3, FIG. 3 is a cross-sectional view illustrating a standardized circuit board core having a four-layered conductive layer of a preferred embodiment of the invention. As shown in FIG. 3, a standard circuit board core 201 having two patterned conductive layers 220a, 220b and two surfaces 210a, 210b is provided. Then two dielectric layers 230a, 230b and two conductive layers 240a, 240b (e.g. formed by copper film layers, or compound metal layers) are piled on both of the surfaces 210a, 210b of the dielectric core layer 210. Then these layers are laminated to form a half-finished four-layer conductive layer printed circuit board. It is worthy of note that the dielectric layer 230a may be a standard circuit board having only a dielectric core layer 210 and a plurality of conductive posts 212. Thus the two adjacent conductive layers 220a and 240a are electrically connected by the conductive posts that are array arranged or in a constant distance form in the dielectric core layer 210. Moreover, the dielectric layer 230b may also be a standard circuit board having the same structure of the dielectric layer 230a. Thus the two adjacent conductive layers 220b and 240b are electrically connected by the conductive posts that are array arranged or in a constant distance form in the dielectric core layer 210.

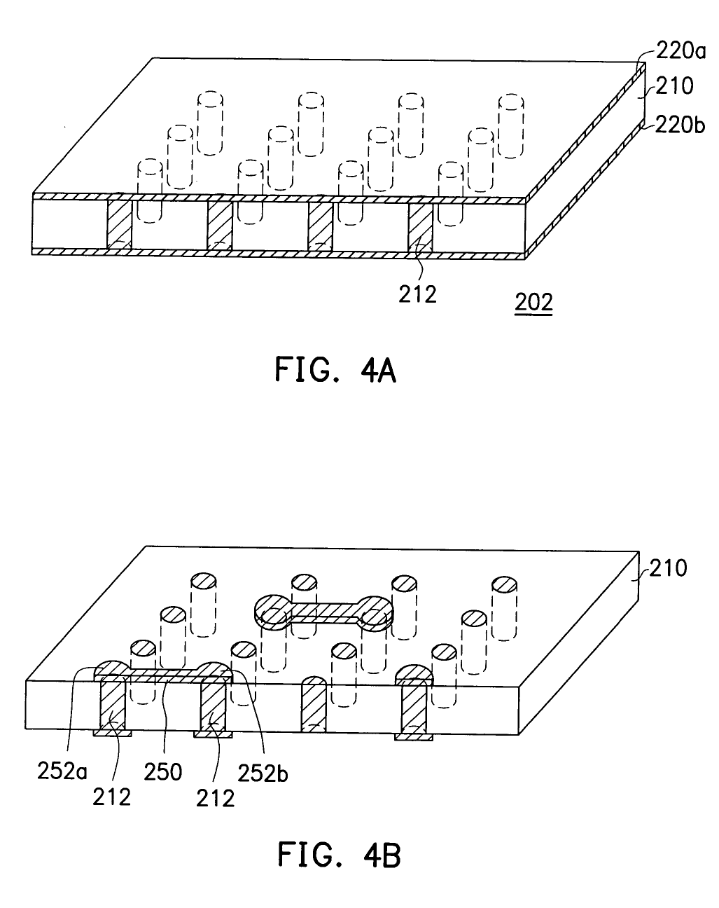

FIG. 4A and 4B are perspective views of a non-patterned and a patterned standardized or partial standardized circuit board core respectively of a preferred embodiment of the invention. As shown in FIG. 4A, the conductive posts 212 of a standardized circuit board core 202 are array arranged or arranged in a constant distance form in a dielectric core layer 210. Thereafter, as shown in FIG. 4B, based on the needs of design, the conductive layers 220a and 220b of the dielectric core layer 210 are patterned in order to form the conductive trace 250 and bonding pad 252a, 252b respectively. The bonding pad 252a can be electrically connected to the bonding pad 252b through the conductive trace 250.

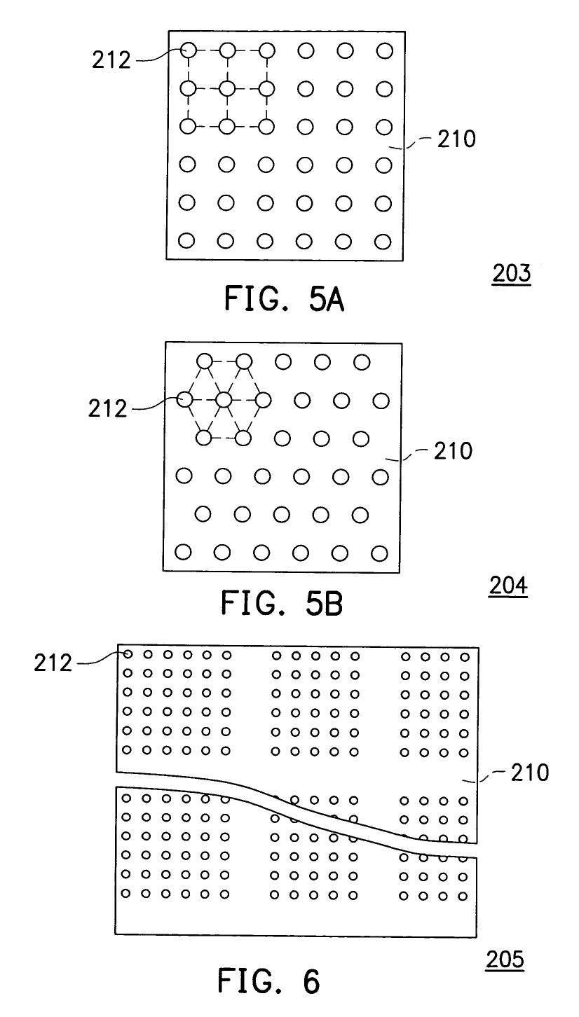

FIG. 5A and FIG. 5B are top views illustrating standardized circuit board cores arranged in two constant distance forms respectively of a preferred embodiment of the invention. First, as shown in FIG. 5A, with respect to a standardized circuit board core 203, the conductive posts 212 are arranged in area array form in a dielectric core layer 210. Moreover, as shown in FIG. 5B, with respect to a standardized circuit board core 204, the conductive posts 212 are arranged in a honeycomb form in a dielectric core layer 210.

FIG. 6 is a top view illustrating a standardized circuit board core having conductive posts partially plugged in a partial standardized circuit board core of a preferred embodiment of the invention. As shown in FIG. 6, with respect to a standardized circuit board core 205, the conductive posts 212 are partially arranged in some areas in a dielectric core layer 210.

Accordingly, the standardized or partial standardized circuit board core of the invention provides a plurality of conductive posts pre-manufactured in all or partial area of the dielectric core layer. These conductive posts are array arranged or arranged in a constant distance form in the dielectric core layer. Therefore, when using the standardized or partial standardized circuit board core to manufacture a printed circuit board, the plated through hole process is no longer needed, thus the two-surfaced conductive layers can be patterned immediately. The manufacturing process of the printed circuit board can be simplified. Therefore the design and manufacture period and the cost of a printed circuit board are reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A standardized circuit board core, comprising:
a dielectric core layer having a first surface and a related second surface; and
a plurality of conductive posts passing through the dielectric core layer and connecting to the first surface and the second surface of the dielectric core layer, wherein the conductive posts are arranged in one form selected from a group of array form and a constant distance form in at least one of the partial areas of the dielectric core layer.

2. The standardized circuit board core of claim 1, wherein further comprises two conductive layers being formed on the first surface and the second surface of the dielectric core layer respectively.
